(19) United States
(12) Patent Application Publication
(10) Pub. No.: US 2002/0017704 A1
(43) Pub. Date: Feb. 14, 2002

(54) Semiconductor device and method of manufacture

(76) Inventor: Takashi Yajima, Tokyo (JP)

Correspondence Address: Darryl G. Walker, WALKER & SAKO, LLP, Suite 235, 300 South First Street, San Jose, CA, 95113, US

(21) Appl. No.: 09/920,135

(22) Filed: Jul. 31, 2001

(30) Foreign Application Priority Data
Aug. 1, 2000 (JP) 2000-232615

(51) Int. Cl. H01L 21/8238; H01L 23/58; H01L 23/62

(52) U.S. Cl. 257/665; 438/215

(57) ABSTRACT

A semiconductor device according to one embodiment may include protruding portions (2) formed on a periphery of a fuse pattern. Narrowed portions (3) are gaps between adjacent protruding portions (2), and may be filled with a first insulation layer (5), such as an oxide or the like. A silica layer (6) may then be deposited for enhancing the flatness of a semiconductor device surface. Excess silica layer (6) portions may be etched back and remaining silica layer (6) between fuses (1) may be planarized. A second insulation layer (7) may be formed that can contact portions of a first insulation layer (5) that fill narrowed portions (3). Consequently, the extents of a silica layer (6) may be interrupted along a periphery and between adjacent fuses by first insulation layer (5).

### TECHNICAL FIELD

The present invention relates generally to a semiconductor device and a method of manufacturing such a device, and more particularly to a semiconductor device having a fuse pattern provided for circuit redundancy and a method of manufacturing such a fuse pattern.

### BACKGROUND OF THE INVENTION

In semiconductor devices, a silica-type material (such as spin-on-glass, called SOG) is often used as a filling and/or insulation layer. Unfortunately, moisture can be capable of propagating through silica-type materials, and adversely affect the reliability or performance of a semiconductor device. As well known in the art, a covering layer (sometimes called a topside or “passivation” layer) may be formed on a surface of a semiconductor device, and thereby prevent moisture from entering the various layers, including silica layer.

However, certain semiconductor device features may still be vulnerable to moisture penetration. One such feature is a fuse pattern, typically included to implement redundancy in a semiconductor device, if needed. Fuse patterns may include fuses formed below “windows” of thinner dielectric materials. Further, in the event a fuse is “opened,” by laser irradiation for example, a covering layer may be blown off, exposing lower layers to moisture.

A typical conventional approach to preventing moisture penetration in a fuse pattern includes forming a surrounding border around a fuse pattern. A drawback to such an arrangement can be the amount of area needed. In particular, it can be necessary to maintain a minimum width between a surrounding border and the fuse pattern.

A first example of a conventional semiconductor device with a fuse pattern is shown in FIGS. 3A to 3C. FIG. 3A is a plan view of fuse pattern. FIG. 3B is a sectional view taken along line A-A′ of FIG. 3A. FIG. 3C is a sectional view taken along line B-B′ of FIG. 3A.

FIG. 3A shows a pattern of fuses 1, surrounded by a border 19. A length of a fuse 1 is shown as 12, a width of a fuse is shown as 13, and a distance between adjacent fuses is shown as 14. In FIG. 3B, an insulating layer 5 is shown formed over fuses 1. An insulating layer 5 may be an oxide layer, for example. Additional insulating layers are shown as 7 and 8. A silica layer is shown as 6.

In the arrangement of FIGS. 3A to 3C, a silica layer 6 may be interrupted at intervals by insulating layer 5 extending upward to meet insulating layer 7. If a fuse 1 is opened, silica 6 may be exposed. However, while moisture may initially enter any exposed silica 6, such moisture is prevented from propagating any further into a semiconductor deice by the above interruptions. A drawback to such an approach can be the amount of area required to include a border 19 that entirely surrounds fuses 1.

Another conventional example of a semiconductor device having fuse patterns is shown in FIGS. 4A and 4B. This is approach is described in Japanese Patent Application, First Publication, No. Hei 9-139431. FIG. 4A is a sectional view of a semiconductor device. FIG. 4B is a plan view of the semiconductor device.

As shown in FIGS. 4A and 4B, a fuse 3 is formed at the bottom of an aperture 11. An aperture 11 may be formed through a covering layer 8, an insulation layer 28, a SOG layer 27 (which may be a silica-type layer), and another insulating layer 4. SOG layer 27 may be included to enhance flatness (i.e., planarity) in a semiconductor device.

In FIGS. 4A and 4B, a dummy lead wire layer 5X is formed around the aperture 11. A dummy lead wire layer 5X may be formed at about the same general level as SOG layer 27, and thus interrupt SOG layer 27 at the periphery of aperture 11. Consequently, even if SOG layer 27 exposed at aperture 11 absorbs moisture, such moisture may be prevented from propagating any further into a semiconductor device by dummy lead wire layer 5X. It is noted that dummy lead wire layer 5X may be covered with a layer 6, which may be an insulating layer.

Yet another example of a semiconductor device with a conventional fuse pattern is shown in FIGS. 5A and 5B. This is approach is proposed in Japanese Patent Application, First Publication, No. Hei 7-263558 to solve the problem of cracking that may occur when fuses are opened. In particular, cracks may propagate through laminated layers around the location where a fuse is melted. FIG. 5A is a plan view of a semiconductor device. FIG. 5B is a sectional view of the device taken along line B-B.

As shown in FIGS. 5A and 5B, a conventional approach may include a semiconductor substrate 21 on which is formed an insulating layer 21a of silicon dioxide (SiO₂), or the like. Fuse lead wires 22 may be formed on the insulating layer 21a from aluminum, and have a width of about 1.5 microns (μm). The fuse lead wires 22 may extend into surrounding circuitry and be separated from one another by about 6.0 to 7.0 μm. A laminated insulation layer 23, formed from SiO₂, or the like, is formed over fuse lead wires 22 and lead wires (not shown in FIGS. 5A and 5B) connected to the fuse lead wires 22. A laminated insulation layer 23 may have a reduced thickness over a region where fuse lead wires 22 are gathered. Such a reduced thickness region can be about 70×30 μm, and is referred to as a redundancy window 24.

FIGS. 5A and 5B also show a crack protection layer 25. A crack protection layer 25 borders fuse lead wires 22 in the vicinity of redundancy window 24, and is formed from the same aluminum layer as fuse lead wires 22. Further, portions of a crack protection layer 25 (arranged vertically in FIG. 5A) may form a unitary structure that includes fuse lead wires 22, and include straight slits (one of which is shown as SL2) that ensures adjacent fuse lead wires 22 are not electrically connected. A straight slit SL2 may extend parallel to the lengthwise direction of fuse lead wires 22. A crack protection layer 25 has a width of about 4 μm, while a straight slit SL2 may have a width of about 1.5 μm.

In the arrangement of FIGS. 5A and 5B, the opening of a fuse lead wire 22 could result in a crack that spreads through laminated insulating layer 23 which surrounds the fuse lead wires 22. However, the propagation of such a crack can be stopped by crack protection layer 25.

As noted, a crack protection layer 25 is formed to surround a periphery of fuse lead wires 22, and at the same time prevent such fuse lead wires 22 from being electrically connected to one another. Accordingly, fuse lead wires 22 do not have to have multi-layered construction in order to bring fuse lead wires 22 to an outside location. This can simplify construction of a semiconductor device. Moreover, no special construction step is needed to form a crack protection layer 25, since such a layer may be patterned at the same time as lead wires 22.

As described in the various above examples, conventional techniques for preventing moisture from penetrating into a semiconductor device by way of a fuse pattern includes forming a surrounding border pattern. However, such border patterns may have minimum width requirements between the border pattern and fuse patterns. Consequently, an overall fuse pattern may be undesirably large.

In light of the above discussion, it would be desirable to arrive at some way of improving the moisture proof characteristics of a fuse pattern. More particularly, it would be desirable to improve the moisture proof characteristics of a fuse pattern that includes silica layers that are interrupted.

It would also be desirable to arrive at a semiconductor device and method of manufacture that includes a fuse pattern with improved moisture proof characteristics that does not necessarily require increasing a pattern size over conventional techniques.

### SUMMARY OF THE INVENTION

According to the present embodiments, a semiconductor device can include a filling layer formed over a fuse pattern. A fuse pattern may include a number of protruding portions formed on a periphery that are separated from one another by gaps. Such gaps may be filled with a first insulation layer that is different than the filling layer.

According to one aspect of the embodiment, a filling layer may be silica or the like, for enhancing flatness in a semiconductor device. Moisture may penetrate a silica filling layer more easily than a first insulation layer, which may comprise an oxide or the like.

According to another aspect of the embodiments, an insulation layer may have a thickness no less than one half the width of the gaps.

According to another aspect of the embodiments, a fuse pattern may include a number of fuse lead wires. Such fuse lead wires may include protruding portions that extend toward and adjacent fuse wire. A protruding portion may be separated from an adjacent fuse lead wire by a gap. A gap may be filled with a first insulation material. The first insulation material may be different than a filling layer formed over fuse lead wires.

According to another aspect of the embodiments, fuse lead wires may be parallel to one another.

According to another aspect of the embodiments, a fuse pattern may include a border. A border may be adjacent to an outermost fuse lead wire, and may be separated from the outermost fuse lead wire by a gap. Such a gap may be filled with a first insulating layer. In one arrangement, a border may have the general shape of the letter C.

According to another aspect of the embodiments, a second insulation layer may be formed over a filling layer and a first insulation layer. More particularly, a second insulation layer may contact portions of a filling layer formed between fuse lead wires, as well as portions of a first insulation layer that are formed over fuse lead wires and in gaps.

According to another aspect of the embodiments, a cover layer may be formed over a second insulation layer. A cover layer can include a window over portions of fuse lead wires.

According to the present embodiments, a method of manufacturing a semiconductor device may include forming at least one protruding portion on fuse lead wires. Gaps may separate protruding portions of one fuse lead wire from an adjacent fuse wire. Such gaps may be filled with a first insulation layer. A flattening layer that includes silica may then be formed. A second insulation layer may be formed over the flattening layer so that the extents of the flattening layer are interrupted by a first insulation layer that fills the gaps.

According to one aspect of the method, a thickness of a first insulation layer may be at least one half the width of the gaps.

According to another aspect of the method, forming a flattening layer can include depositing the flattening layer, etching back excess portions of a flattening layer, and planarizing remaining portions of the flattening layer between fuse lead wires.

According to another aspect of the method, forming a second insulation layer includes forming the second insulation layer to contact portions of the filling layer that are between fuse lead wires. A second insulation layer may also contact portions of the first insulation layer formed over fuse lead wires and in the gaps.

According to another aspect of the method, a cover layer may be formed over the second insulation layer.

### BRIEF DESCRIPTION OF THE DRAWINGS

FIG. 1A is a plan view of a semiconductor device according to a preferred embodiment of the present invention.

FIG. 1B is a sectional view taken along the plane shown by line A-A′ in FIG. 1A.

FIG. 1C is a sectional view taken along the plane shown by line B-B′ in FIG. 1A.

FIG. 1D is an enlarged sectional view of a gap according to the embodiment of FIG. 1A.

FIG. 2A is a plan view of a semiconductor device according to a preferred embodiment after a covering layer has been opened and a laser trimming is performed.

FIG. 2B is a sectional view taken along the plane shown by line C-C′ in FIG. 2A.

FIG. 2C is a sectional view taken along the plane shown by line D-D′ in FIG. 2A.

FIG. 2D is an enlarged plan view showing a gap according to the embodiment of FIG. 2A.

FIG. 3A is a plan view of a first conventional example of a semiconductor device.

FIG. 3B is a sectional view taken along the plane shown by line A-A′ in FIG. 3A.

FIG. 3C is a sectional view taken along the plane shown by arrows B-B′ in FIG. 3A.

FIG. 4A is a sectional view of a second conventional example of a semiconductor device.

FIG. 4B is a plan view of a second conventional example of a semiconductor device.

FIG. 5A is a plan view of a third conventional example of a semiconductor device.

FIG. 5B is a sectional view taken along the plane shown by arrow B-B in FIG. 5A.

### DETAILED DESCRIPTION OF THE EMBODIMENTS

A preferred embodiment of the present invention will now be described with reference to the accompanying drawings.

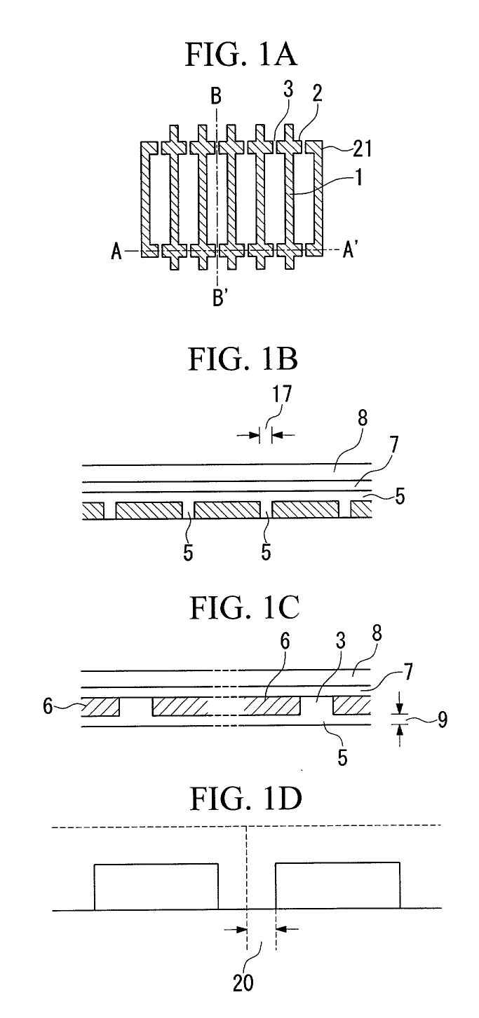

Referring now to FIGS. 1A to 1D a semiconductor device according to a preferred embodiment is shown in a series of drawings. FIG. 1A is a plan view of a semiconductor device. FIG. 1B is a sectional view taken along the plane shown by line A-A′ in FIG. 1A. FIG. 1C is a sectional view taken along the plane shown by line B-B′ in FIG. 1A. FIG. 1D is an enlarged sectional view showing a filled gap according to the example shown in FIG. 1A.

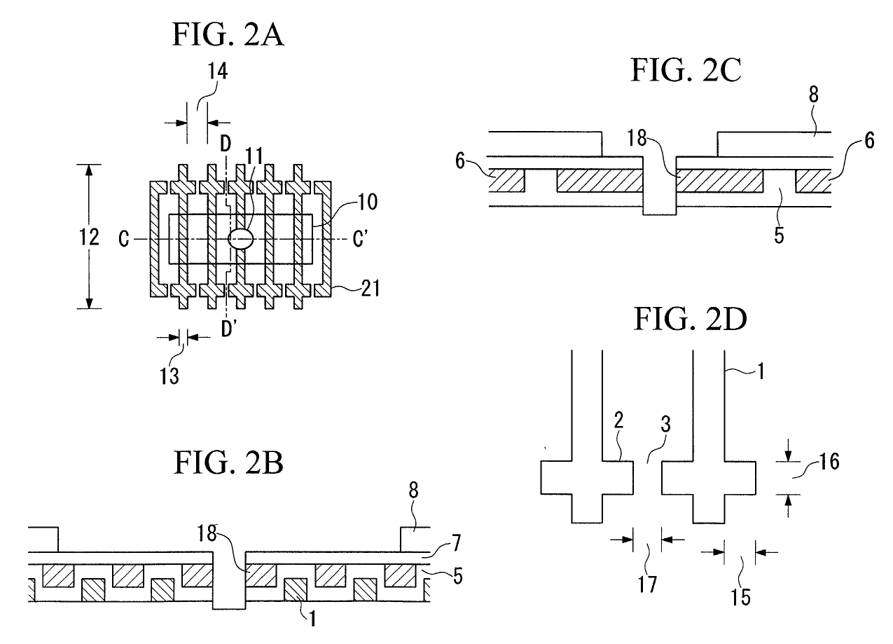

FIGS. 2A to 2D show a semiconductor device, such as that shown in FIGS. 1A to 1D, after a covering layer has been opened and a laser trimming has been performed. FIG. 2B is a sectional view taken along the plane shown by line C-C′ in FIG. 2A. FIG. 2C is a sectional view taken along the plane shown by line D-D′ in FIG. 2A. FIG. 2D is an enlarged plane view showing a portion that is narrowed and forms a gap.

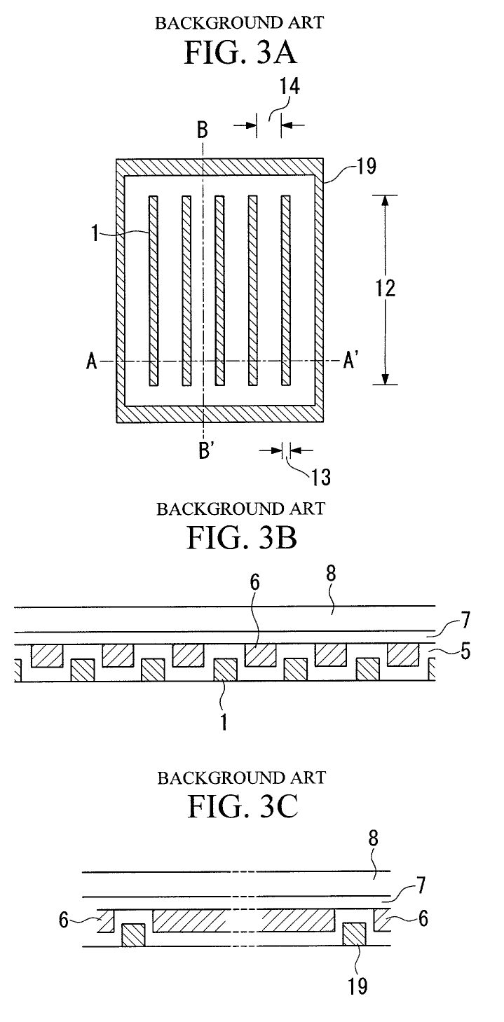

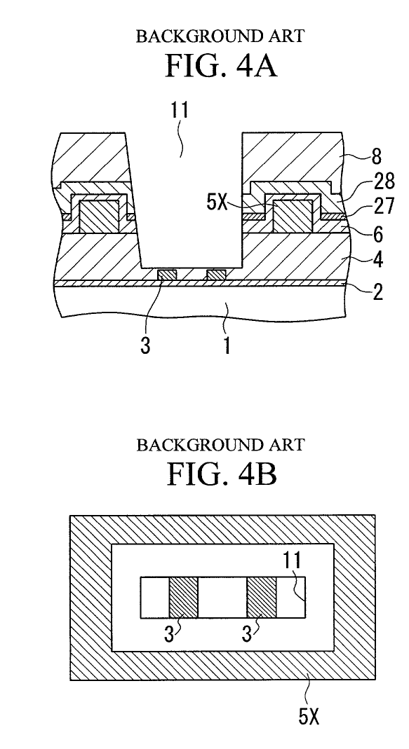

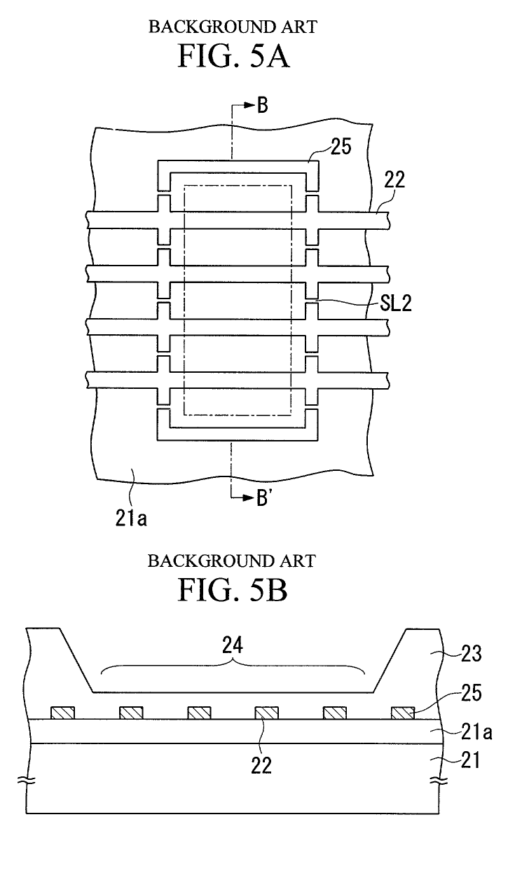

In FIGS. 1A to 2D, some members may have similar structures as that of the semiconductor device shown in FIGS. 3A to 3C. Accordingly, such members are referred to by the same reference character, thus descriptions thereof are omitted.

FIG. 1A shows fuses, one of which is shown as item 1 that include protruding portions 2. Protruding portions 2 may be formed on the flanks of fuses 1. Spacing between adjacent protruding portions 2 results in portions 3 that are narrowed. FIG. 1A also shows that a C-shaped border pattern 21 may be included at peripheral ends of a fuse pattern.

FIG. 1B shows show a sectional view through fuses 1 and protruding portions 2. As shown, portions 3 that are narrowed may be filled with a first insulation layer 5, which may be an oxide, or the like. A width for a portion 3 is shown as item 17. A second insulation layer 7 may be formed over first insulation layer 5. A cover layer 8 can be formed over second insulation layer 7.

FIG. 1C shows a sectional view between fuses 1 and through portions 3. As shown, at portions 3, a first insulation layer 5 may extend up to a second insulation layer 7. A thickness of first insulation layer 5 is shown as item 9. Silica layer 6 may be formed over first insulation layer 5, and interrupted at portions 3. Cover layer 8 can be formed over second insulation layer 7.

FIG. 1D shows an enlarged sectional view of a portion 3 that has been narrowed. An essentially half-width value for a portion 3 is shown as 20. One skilled in the art would understand that making a first insulating layer equal to, or greater than 20, can help to ensure portions 3 are filled with a first insulating layer.

A method of manufacture for a semiconductor device will now be described with reference to FIGS. 1A to 1D. Fuses 1, protruding portions 2, and C-shaped patterns 21 may be formed. Adjacent protruding portions 2 may be separated from one another by portions 3 that are narrowed. First insulating layer 5 may be formed on fuses 1, protruding portions 2, and C-shaped patterns 21. A thickness 9 of first insulating layer 5 may be equal to or greater than a measurement 20, which may be about one half a width of a portion 3. In this way, a portion 3 that is narrowed may be filled with a first insulating layer 5.

A silica layer 6 may be formed over a first insulating layer 5 in order to flatten, or planarize a resulting structure. Excess silica of a silica layer 6 may then be removed by an etch back step. Silica layer 6 may further be flattened (e.g., planarized) between fuses 1. As illustrated by FIG. 1C, such flattening/planarizing steps can help to ensure that silica layer 6 does not extend above a first insulating layer 5 at portions 3 that are narrowed.

A second insulating layer 7 may be formed over silica layer 6. A second insulating layer 7 in combination with portions of a first insulating layer 5, may thus interrupt a silica layer 6, particularly at narrow portions 3, as clearly shown in FIG. 1C.

A cover layer 8 may then be formed over second insulating layer 7.

In this way, a semiconductor device may be formed with fuse structures that includes high moisture resistance. As noted above, silica-type materials, such as a spin-on-glass (SOG) silica layer 6, can conventionally be subject to faults, such as swelling and layer cracking, or the like. This is due to the moisture absorbing characteristics of silica-type materials, and the fact that such materials may be exposed by a fuse opening process. However, the present invention includes structures that interrupt silica layer 6 pathways, thereby limiting the propagation of moisture through a silica layer 6.

Moisture resistance of the present invention will now be described in more detail with reference to FIGS. 2A to 2D.

FIG. 2A shows the same general view as FIG. 1A, however a portion of a covering layer 8 has been removed. Such a removed portion is indicated by the reference character 10. In addition, a track 11 for a trimming laser is also shown. A track 11 may result when a fuse 1 is opened, for example. FIG. 2A also shows a fuse width 13, a spacing 14 between adjacent fuses 1, and a fuse length 12.

FIG. 2B is a sectional view of a plane passing through a track 11. As shown, a track 11 may result in a silica layer 18 being stripped bare. However, such an exposed portion of a silica layer 18 may be interrupted by a first insulation layer 5 formed over a fuse 1 that extends up to a second insulation layer 7. In this way, moisture from a silica layer 18 exposed by fuse opening process can be prevented from propagating in one direction (laterally with respect to FIGS. 2A and 2B).

FIG. 2C shows a sectional view between fuses 1 and through portions 3 and track 11. As shown, a track 11 may result in a silica layer 18 being stripped bare. However, such an exposed portion of a silica layer 18 may be interrupted by a first insulation layer 5 that fills portions 3 that are narrowed and extends up to a second conductive layer 7. In this way, moisture from a silica layer 18 exposed by fuse opening process can be prevented from propagating in a second direction (vertically with respect to FIG. 2A and laterally with respect to 2B).

FIG. 2D is an enlarged plan view of a semiconductor device showing a portion 3 that is narrowed, two adjacent fuses 1, and protruding portions 2. A width of protruding portions 2 in a vertical direction is shown as 16. A length of protruding portions 2 in a horizontal direction is shown as 15. A gap 17 between protruding portions 2, which can correspond to a portion 3, is also shown in FIG. 2D.

In this way, a semiconductor device according to the disclosed embodiments may interrupt a layer of silica that may be exposed by a fuse opening process in all directions. It is noted that such a moisture resistant benefit can be obtained without enlarging an overall size of a fuse pattern as protruding portions 2 and C-shaped patterns 21 are arranged around a periphery of a fuse pattern. Accordingly, if a silica-type material (such as SOG) is used above lead wires used as fuses, moisture resistant characteristics may be retained, without making the fuse pattern any larger.

It is noted that C-shaped patterns 21 can prevent the propagation of moisture into interior portions of a semiconductor device from a fuse pattern when end fuses are opened (i.e., a far left fuse or far right fuse in FIGS. 1A and 2A).

An example containing various particular dimensions will now be described. Fuses may have a length of 12 microns μm, a width of 1 μm, and be separated from one another by 2 μm. Protruding portions 15 may have a length of 0.8 μm and a width of 1 μm, and be separated from one another by a gap 17 of 0.4 μm. In such an arrangement, a first insulation layer 5 may have a thickness of 200 nanometers (nm) or greater at a sidewall coverage of 50%. This can fill portions 3 that are narrowed, and so interrupt a silica layer 6.

In the case where a number of fuses is 5, a fuse pattern according to the above measurements may have an area of 10 μm×(6×3+1) μm=190 μm². In contrast, a similar set of fuses according to a prior art approach that includes a surrounding border may be (10+3×2) μm×(6×3+1) μm=304 μm². Therefore, the above example of the present invention may provide a moisture resistant fuse pattern having but 62.5% of the area of prior art approaches.

It is understood that while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a filling layer formed over at least a portion of a fuse pattern; and
a plurality of protruding portions arranged on the periphery of the fuse pattern separated from one another by gaps filled with an insulation layer that is different than the filling layer.

2. The semiconductor device according to claim 1, wherein:
moisture penetrates the filling layer more easily than the insulation layer.

3. The semiconductor device according to claim 1, wherein:
the insulation layer comprises an oxide.

4. The semiconductor device according to claim 1, wherein:
the thickness of the insulation layer is no less than half the thickness of the gaps.

5. The semiconductor device according to claim 1, wherein:
the filling layer comprises a silica layer for enhancing flatness of a semiconductor device surface.

6. A semiconductor device, comprising:
a plurality of fuse lead wires, each having at least one protruding portion that extends towards an adjacent fuse lead wire and separated therefrom by a gap; and
an insulation layer that fills the gaps comprising a different material than a filling layer formed over the fuse lead wires.

7. The semiconductor device according to claim 6, wherein:
the fuse lead wires are essentially parallel to one another.

8. The semiconductor device according to claim 6, wherein:
the insulation layer comprises an oxide.

9. The semiconductor device according to claim 6, wherein:
the fuse lead wires include at least one outermost fuse lead wire that includes at least one protruding portion that extends way from the other fuse lead wires; and
a fuse pattern border formed adjacent to the outermost fuse lead wire and opposite the other fuse lead wires that is separated from the at least one protruding portion of the outermost fuse lead wire by a gap that is filled with the first insulating layer.

10. The semiconductor device according to claim 9, wherein:
the fuse pattern border has a letter C shape.

11. The semiconductor device according to claim 6, wherein:
the thickness of the insulation layer is no less than half the thickness of the gaps.

12. The semiconductor device according to claim 6, wherein:
the filling layer comprises silica.

13. The semiconductor device according to claim 6, further including:
a second insulation layer formed over the fuse lead wires that contacts filling layer portions between fuse lead wires and first insulation portions formed over the fuse lead wires and in the gaps.

14. The semiconductor device according to claim 6, further including:
forming a cover layer over the second insulation layer that includes a window over portions of the fuse lead wires.

15. A method of manufacturing a semiconductor device, comprising the steps of:
forming a t least one protruding portion on fuse lead wires;
filling gap s separating the protruding portion of one fuse lead wire from an adjacent fuse lead wires with a first insulation layer;
forming a flattening layer comprising silica; and
forming a second insulation layer; wherein
extents of the flattening layer are interrupted by the first insulation layer that fills the gaps.

16. The method of claim 15, wherein:
the thickness of the first insulation layer is at least one half a width of the gaps.

17. The method of claim 15, wherein:
forming the flattening layer includes depositing the flattening layer, etching back excess portions of the flattening layer, and planarizing remaining flattening layer that exists between the fuse lead wires.

18. The method of claim 15, wherein:
forming the second insulation layer includes forming the second insulation layer to contact filling layer portions between fuse lead wires and first insulation portions formed over the fuse lead wires and in the gaps.

19. The method of claim 15, further including:
forming a cover layer over the second insulation layer.

20. The method of claim 19, further including:
forming a window in the cover layer over portions of the fuse lead wires.
